(19) United States
(12) Patent Application Publication
(10) Pub. No.: US 2007/0296512 A1
(43) Pub. Date: Dec. 27, 2007

(54) Voltage-controlled crystal oscillator

(76) Inventors: Masayuki Yokoyama, Tokyo (JP); Motoki Sakai, Kanagawa (JP)

Correspondence Address: MCDERMOTT WILL & EMERY LLP, 600 13TH STREET, NW, WASHINGTON, DC, 20005-3096, US

(21) Appl. No.: 11/812,413

(22) Filed: Jun. 19, 2007

(30) Foreign Application Priority Data
Jun. 22, 2006 (JP) 2006-172374

(51) Int. Cl. H03L 7/00

(52) U.S. Cl. 331/34

(57) ABSTRACT

A voltage-controlled crystal oscillator having a voltage-variable capacitive element and a crystal vibrator, includes a control voltage generating circuit, a first charging circuit which charges an output-side capacitive component, a low pass filter having a first resistor and a first fixed capacitor, a timer circuit which outputs a control signal, a first switching element which is turned on in response to the control signal from the timer circuit so as to make both ends of the first resistor open-circuited, a second charging circuit to which a signal synchronized with the control signal is input, and a second fixed capacitor to which an output terminal of the second charging circuit is connected, and which connects a connection point between the first resistor and the first fixed capacitor. The low pass filter is arranged between the voltage-variable capacitive element and a connection point of the control voltage generating circuit and the first charging circuit.

### BACKGROUND OF THE INVENTION

The present invention relates to a voltage-controlled crystal oscillator having a low pass filter for eliminating noises.

Crystal oscillators are widely used for cellular phones or the like because stabilized frequencies can be obtained. In recent years, as cellular phones use high frequency bands, noise reduction for realizing high-quality communication is requested to components mounted in the cellular phones in order to prevent interference with frequency bands used by, other sets. Moreover, in the field of cellular phone technology, a cellular phone is requested to have multiple functions including a GPS (global positioning system) function or the like. Accordingly, as for the components mounted in the cellular phone, realization of low noise and highly stable oscillation is very important.

Hereinafter, a related voltage-controlled crystal oscillator will be described with reference to FIG. 1. The related voltage-controlled crystal oscillator includes an amplifier 15, a feedback circuit 14 that is connected in parallel to the amplifier 15, a first voltage-variable capacitive element 12 that is connected to the input terminal of the amplifier 15 with a fixed capacitor 10 interposed therebetween, and a second voltage-variable capacitive element 13 that is connected to the output terminal of the amplifier 15 with a fixed capacitor 11 interposed therebetween.

Further, a crystal vibrator 16 is connected between a connection point of the input-side fixed capacitor 10 and the first voltage-variable capacitive element 12 and a connection point of the output-side fixed capacitor 11 and the second voltage-variable capacitive element 13, thereby forming a crystal oscillator 17.

Furthermore, a low pass filter including a first resistor 3 and a first fixed capacitor 5 is connected to a control voltage generating circuit 1 and a first charging circuit 2 for electrically charging an output-side capacitive component, and an output terminal of the low pass filter is connected to cathodes of the first voltage-variable capacitive element 12 and second voltage-variable capacitive element 13 of the crystal oscillator 17 with resistors 8 and 9 interposed therebetween. In addition, both ends of the first resistor 3 are open-circuited at the start of oscillation by turning on a first switching element 4 that is controlled by a control signal from a timer circuit 18, thereby forming a low-noise voltage-controlled crystal oscillator (for example, refer to JP-UM-A-6-34319).

Hereinafter, a problem to be solved will be described with reference to FIGS. 1 to 5. As shown in FIG. 1, in the voltage-controlled crystal oscillator to which a control voltage is applied through the low pass filter including the first fixed capacitor 5 and the first resistor 3 connected with the first switching element 4 which is turned on at the start of operation, when both the ends of the first resistor 3 are open-circuited after a power voltage is applied, the control voltage applied through the first resistor 3 fluctuates with a large time constant due to influences of parasitic resistor 7 and parasitic capacitor 6 generated in the first fixed capacitor 5.

As described above, the first fixed capacitor 5 for realization of low noise has the parasitic capacitor 6 and the parasitic resistor 7 connected in parallel therewith. Accordingly, as shown in FIG. 5, at time 402 when the first switching element 4 becomes open-circuited from a short-circuited state after the power voltage is applied, an output voltage 404 of the control voltage generating circuit 1 output through the first resistor 3 fluctuates with a time constant 403 determined by the first resistor 3, the first fixed capacitor 5, the parasitic capacitor 6, and the parasitic resistor 7. As a result, a problem occurs in that it takes long time until an oscillation frequency of the crystal oscillator 17 is stabilized.

### SUMMARY OF THE INVENTION

The invention has been finalized in view of the drawbacks inherent in the related art, and it is an object of the invention to provide a voltage-controlled crystal oscillator capable of realizing a low noise performance and oscillating a stabilized frequency within a short period of time after supply of power.

In order to achieve the above object, according to the present invention, there is provided a voltage-controlled crystal oscillator having a voltage-variable capacitive element and a crystal vibrator connected to the voltage-variable capacitive element, comprising:

a control voltage generating circuit;

a first charging circuit which charges an output-side capacitive component;

a low pass filter having a first resistor and a first fixed capacitor;

a timer circuit which outputs a control signal;

a first switching element which is turned on in response to the control signal from the timer circuit so as to make both ends of the first resistor open-circuited;

a second charging circuit to which a signal synchronized with the control signal is input; and

a second fixed capacitor to which an output terminal of the second charging circuit is connected, and which connects a connection point between the first resistor and the first fixed capacitor,

wherein the low pass filter is arranged between the voltage-variable capacitive element and a connection point of the control voltage generating circuit and the first charging circuit.

In the case in which both ends of the first resistor are open-circuited at the start of oscillation (at the time of supply of power), an output voltage of the control voltage generating circuit fluctuates due to the first resistor and the first fixed capacitor included in the low pass filter. However, in the configuration described above, it is possible to generate a voltage having an opposite polarity with respect to the fluctuation of the output voltage of the control voltage generating circuit. Accordingly, it is possible to suppress the oscillation frequency of the crystal oscillator from fluctuating due to the fluctuation of the output voltage of the control voltage generating circuit, and it is possible to oscillate a stabilized frequency within a short period of time after supply of power. As a result, it is possible to obtain a stabilized oscillation frequency while realizing a low noise performance.

Preferably, the second charging circuit includes a constant current source, a second switching element to which the signal synchronized with the control signal from the timer circuit is input, and which is connected in series with the constant current source, and a voltage restricting element which is connected in parallel with the second switching element. A connection point of the constant current source and the second switching element is connected to the second fixed capacitor.

According to the configuration described above, since the voltage restricting element restricts a voltage so as not to be higher than the output voltage of the control voltage generating circuit, it is possible to compensate the output of the control voltage generating circuit with high precision.

Preferably, the second charging circuit includes a third switching element to which a signal synchronized with the control signal from the timer circuit is input, and which restricts supply of power, a second resistor which is connected in series with the third switching element, a third fixed capacitor which is connected in series with the second resistor, and a voltage restricting element which is connected in parallel with the third fixed capacitor. A connection point of the second resistor and the third fixed capacitor is connected to the second fixed capacitor.

According to the configuration described above, since the voltage restricting element restricts a voltage so as not to be higher than the output voltage of the control voltage generating circuit, it is possible to compensate the output of the control voltage generating circuit with high precision.

Preferably, the second charging circuit includes a third switching element to which the signal synchronized with the control signal from the timer circuit is input, and which restricts supply of power, a second resistor which is connected in series with the third switching element, a third resistor which is connected in series with the second resistor, and a fourth fixed capacitor connected in parallel with the third resistor. A connection point of the second resistor and the third resistor is connected to the second fixed capacitor.

According to the configuration described above, since a voltage is divided by the first and third resistors so as not to be higher than output voltage of the control voltage generating circuit, it is possible to compensate the output of the control voltage generating circuit with high precision.

In the voltage-controlled crystal oscillator according to the aspect of the invention, it is possible to generate a voltage having an opposite polarity with respect to the fluctuation of the output voltage of the control voltage generating circuit. Accordingly, it is possible to suppress the oscillation frequency of the crystal oscillator from fluctuating due to the fluctuation of the output voltage of the control voltage generating circuit, and it is possible to oscillate a stabilized frequency within a short period of time after supply of power. As a result, it is possible to obtain a stabilized oscillation frequency, while realizing a low noise performance in the same manner as in the known circuit.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a view illustrating the configuration of a voltage-controlled crystal oscillator in the related art;

FIG. 2 is a view illustrating the configuration of a voltage-controlled crystal oscillator according to a first embodiment of the invention;

FIG. 3 is a view illustrating the configuration of a voltage-controlled crystal oscillator according to a second embodiment of the invention;

FIG. 4 is a view illustrating the configuration of a voltage-controlled crystal oscillator according to a third embodiment of the invention;

FIG. 5 is a view illustrating an example of a control voltage of a known voltage-controlled crystal oscillator;

FIG. 6 is a view illustrating an example of a control voltage of the voltage-controlled crystal oscillator according to the embodiment of the invention; and

FIG. 7 is a view illustrating an example of an output voltage of a charging circuit of the voltage-controlled crystal oscillator according to the embodiment of the invention.

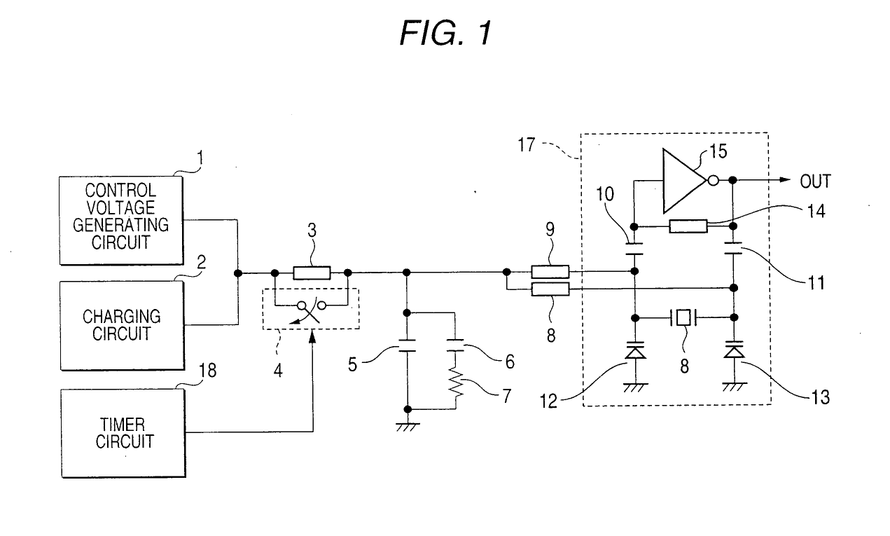

### DETAILED DESCRIPTION OF THE PREFERRED EMBODIMENTS

### First Embodiment

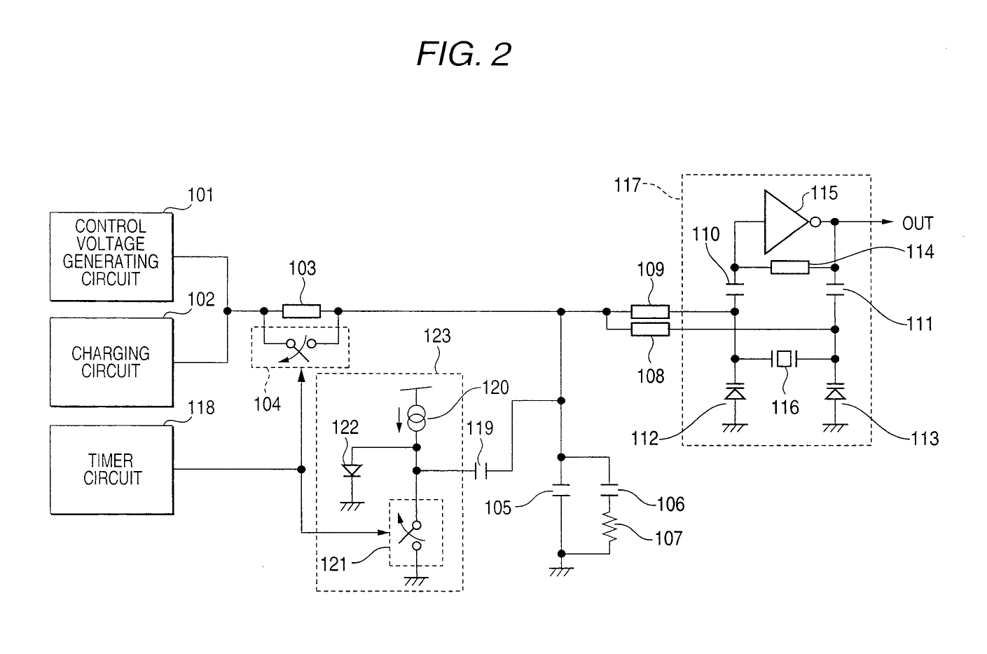

Hereinafter, an example of the configuration of a low-noise oscillating circuit, in which an oscillation frequency is stabilized, according to a first embodiment of the invention will be described with reference to the accompanying drawings. FIG. 2 is a view explaining the schematic configuration of a voltage-controlled crystal oscillator according to the first embodiment of the invention.

The voltage-controlled crystal oscillator according to the first embodiment of the invention includes an amplifier 115, a feedback circuit 114 that is connected in parallel to the amplifier 115, a first voltage-variable capacitive element 112 that is connected to the input terminal of the amplifier 115 through a fixed capacitor 110, and a second voltage-variable capacitive element 113 that is connected to the output terminal of the amplifier 115 through a fixed capacitor 111.

Further, a crystal vibrator 116 is connected between a connection point of the input-side fixed capacitor 110 and the first voltage-variable capacitive element 112 and a connection point of the output-side fixed capacitor 111 and the second voltage-variable capacitive element 113, thereby forming a crystal oscillator 117.

Furthermore, an input terminal of a low pass filter including a first resistor 103 and a first fixed capacitor 105 is connected to a control voltage generating circuit 101 and a first charging circuit 102 for electrically charging an output-side capacitive component, and an output terminal of the low pass filter is connected to cathodes of the first voltage-variable capacitive element 112 and second voltage-variable capacitive element 113 of the crystal oscillator 117 through resistors 108 and 109. Both ends of the first resistor 103 are open-circuited at the start of oscillation by turning on a first switching element 104 that is controlled by a control signal from a timer circuit 118.

Furthermore, in the present embodiment, the timer circuit 118 is connected to an input terminal of a second charging circuit 123, and an output terminal of the second charging circuit 123 is connected to an end of a second fixed capacitor 119, thereby forming the voltage-controlled crystal oscillator. The second charging circuit 123 includes a constant current source 120 from which a constant current is supplied, a second switching element 121 to which a second control signal synchronized with the first control signal is input, and a voltage restricting element 122 which restricts a voltage so as not to be higher than an output voltage of the control voltage generating circuit 101. the constant current source 120, the second switching element 121 and the voltage restricting element 122 are connected with each other.

FIG. 6 is a view illustrating an output voltage of the control voltage generating circuit 101 in the voltage-controlled crystal oscillator according to the present embodiment. Moreover, FIG. 7 is a view illustrating an output voltage of the second charging circuit 123 in the voltage-controlled crystal oscillator according to the present embodiment.

As shown in FIGS. 6 and 7, in the voltage-controlled crystal oscillator according to the present embodiment, an output voltage 504 of the control voltage generating circuit and an output voltage 605 of the second charging circuit 123 can be changed at the same time by making equal (matching) time 502 at which the first switching element 104 is switched and time 602 at which the second switching element 121 is switched.

In addition, temporal compensation is realized by making a time constant 603, which is created in the constant current source 120 and the second fixed capacitor 119, equal to the time constant 403.

Moreover, by matching a capacitive value of the second fixed capacitor 119 with that of a parasitic capacitor 106 of the first fixed capacitor 105 using a trimming method or the like, a current transiently charged in the parasitic capacitor 106 is compensated by a current discharged from the second fixed capacitor 119.

Furthermore, voltage compensation is realized by causing an output voltage level 501 of the control voltage generating circuit 101 and a voltage level 601 restricted by the voltage restricting element 122 to be equal to each other.

Thus, it is possible to stabilize an oscillation frequency of the crystal oscillator 117 within a short period of time by compensating the output voltage 504 of the control voltage generating circuit 101 with high precision.

### Second Embodiment

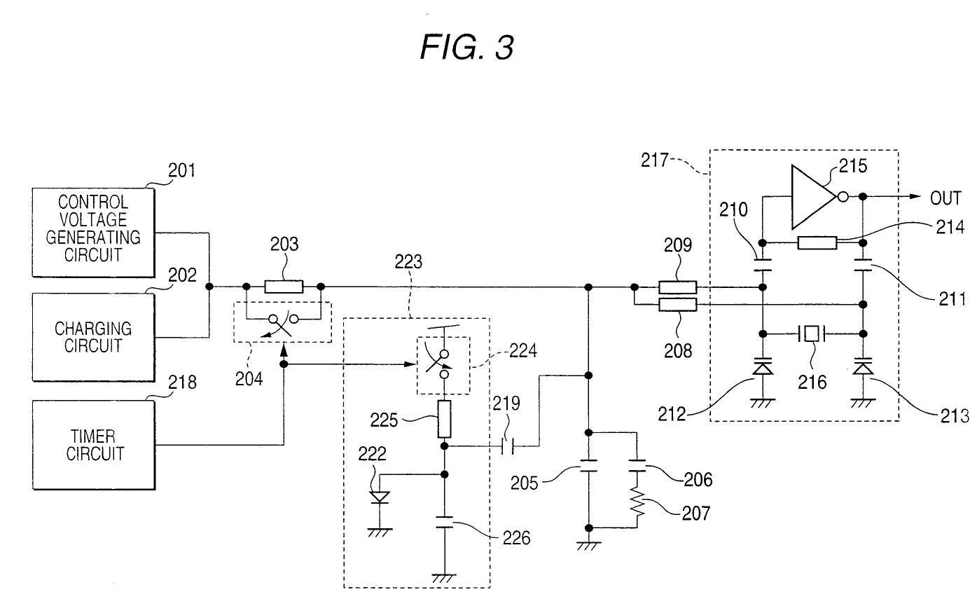

Hereinafter, an example of the configuration of a low-noise oscillating circuit, in which an oscillation frequency is stabilized, according to a second embodiment of the invention will be described with reference to the accompanying drawings. FIG. 3 is a view explaining the schematic configuration of a voltage-controlled crystal oscillator according to the second embodiment of the invention.

The voltage-controlled crystal oscillator according to the second embodiment of the invention includes an amplifier 215, a feedback circuit 214 that is connected in parallel to the amplifier 215, a first voltage-variable capacitive element 212 that is connected to the input terminal of the amplifier 215 through a fixed capacitor 210, and a second voltage-variable capacitive element 213 that is connected to the output terminal of the amplifier 215 through a fixed capacitor 211.

Further, a crystal vibrator 216 is connected between a connection point of the input-side fixed capacitor 210 and the first voltage-variable capacitive element 212 and a connection point of the output-side fixed capacitor 211 and the second voltage-variable capacitive element 213, thereby forming a crystal oscillator 217.

Furthermore, an input terminal of a low pass filter including a first resistor 203 and a first fixed capacitor 205 is connected to a control voltage generating circuit 201 and a first charging circuit 202 for electrically charging an output-side capacitive component, and an output terminal of the low pass filter is connected to cathodes of the first voltage-variable capacitive element 212 and second voltage-variable capacitive element 213 of the crystal oscillator 217 through resistors 208 and 209. In addition, both ends of the first resistor 203 are open-circuited at the start of oscillation by turning on a first switching element 204 that is controlled by a control signal from a timer circuit 218.

In addition, the timer circuit 218 is connected to an input terminal of a second charging circuit 223, and an output terminal of the second charging circuit 223 is connected to an end of a second fixed capacitor 219, to which the first fixed capacitor 205 is connected, thereby forming the voltage-controlled crystal oscillator. The second charging circuit 223 includes a second switching element 224 which restricts supply of power and to which a second control signal synchronized with the first control signal is input, a second resistor 225 which is connected to the second switching element 224, a voltage restricting element 222 which restricts a voltage so as not to be higher than an output voltage of the control voltage generating circuit 201, and a third fixed capacitor 226 which is connected to the voltage restricting element 222 and the second resistor 225.

As shown in FIGS. 6 and 7, in the voltage-controlled crystal oscillator according to the present embodiment, the output voltage 504 of the control voltage generating circuit and an output voltage 605 of the second charging circuit 223 can be changed at the same time by making equal the time 502 at which the first switching element 204 is switched and the time 602 at which the second switching element 224 is switched.

In addition, temporal compensation is realized by making the time constant 603, which is created in the second resistor 225 and the third fixed capacitor 226, equal to the time constant 403.

Moreover, by matching a capacitive value of the second fixed capacitor 219 with that of a parasitic capacitor 206 of the first fixed capacitor 205 using a trimming method or the like, a current transiently charged in the parasitic capacitor 206 is compensated by a current discharged from the second fixed capacitor 219.

Furthermore, voltage compensation is realized by causing the output voltage level 501 of the control voltage generating circuit 201 and the voltage level 601 restricted by the voltage restricting element 222 to be equal to each other.

Thus, it is possible to stabilize an oscillation frequency of the crystal oscillator 217 within a short period of time by compensating the output voltage 504 of the control voltage generating circuit 201 with high precision.

### Third Embodiment

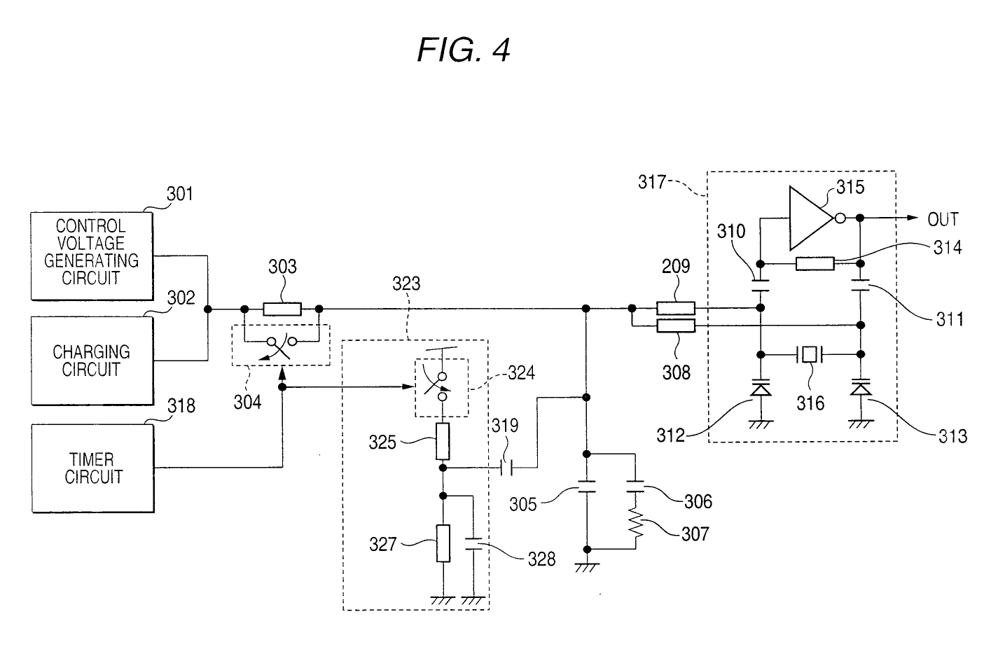

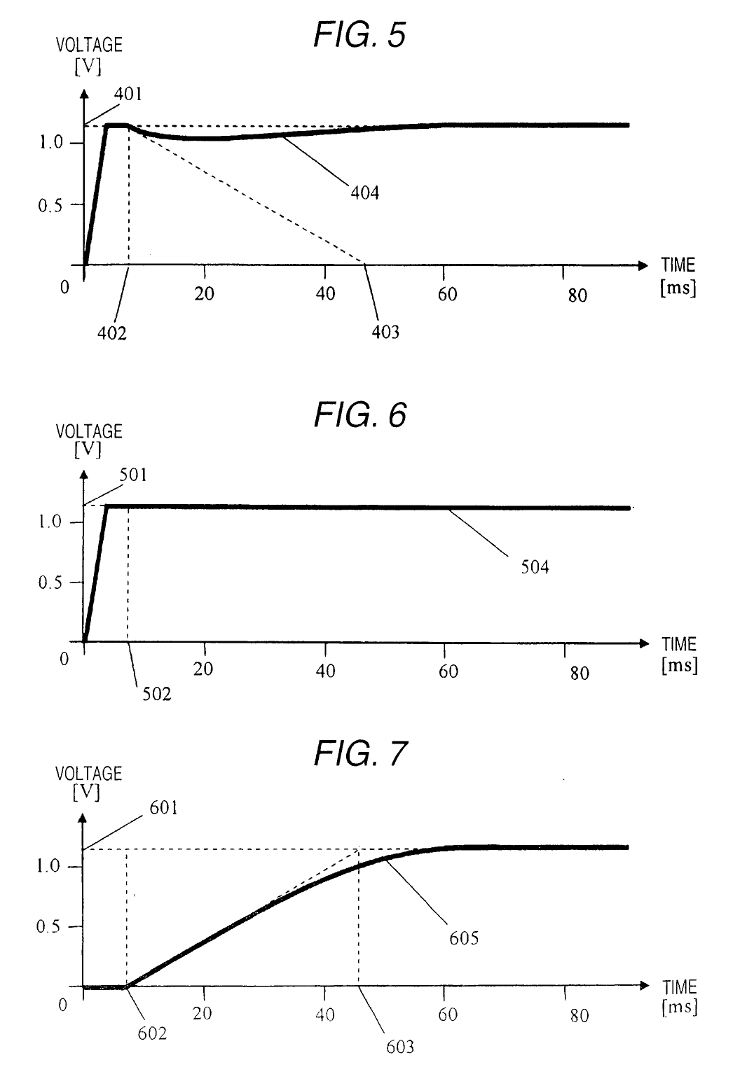

Hereinafter, an example of the configuration of a low-noise oscillating circuit, in which an oscillation frequency is stabilized, according to a third embodiment of the invention will be described with reference to the accompanying drawings. FIG. 4 is a view explaining the schematic configuration of a voltage-controlled crystal oscillator according to the third embodiment of the invention.

The voltage-controlled crystal oscillator according to the third embodiment of the invention includes an amplifier 315, a feedback circuit 314 that is connected in parallel to the amplifier 315, a first voltage-variable capacitive element 312 that is connected to the input terminal of the amplifier 315 through a fixed capacitor 310, and a second voltage-variable capacitive element 313 that is connected to the output terminal of the amplifier 315 through a fixed capacitor 311.

Further, a crystal vibrator 316 is connected between a connection point of the input-side fixed capacitor 310 and the first voltage-variable capacitive element 312 and a connection point of the output-side fixed capacitor 311 and the second voltage-variable capacitive element 313, thereby forming a crystal oscillator 317.

Furthermore, an input terminal of a low pass filter including a first resistor 303 and a first fixed capacitor 305 is connected to a control voltage generating circuit 301 and a first charging circuit 302 for electrically charging an output-side capacitive component, and an output terminal of the low pass filter is connected to cathodes of the first voltage-variable capacitive element 312 and second voltage-variable capacitive element 313 of the crystal oscillator 317 through resistors 308 and 309. In addition, both ends of the first resistor 303 are open-circuited at the start of oscillation by turning on a first switching element 304 that is controlled by a control signal from a timer circuit 318.

In addition, the timer circuit 318 is connected to an input terminal of a second charging circuit 323, and an output terminal of the second charging circuit 323 is connected to an end of a second fixed capacitor 319, thereby forming the voltage-controlled crystal oscillator.

The second charging circuit 323 includes a second switching element 324 which restricts supply of power and to which a second control signal synchronized with the first control signal is input, a second resistor 325 which is connected to the second switching element 324, a third resistor 327 which is connected to the second resistor 325 and which divides a voltage so as not to be higher than an output voltage of the control voltage generating circuit 301, and a third fixed capacitor 328 which is connected to a contact portion between the second resistor 327 and the second resistor 325.

As shown in FIGS. 6 and 7, in the voltage-controlled crystal oscillator according to the present embodiment, the output voltage 504 of the control voltage generating circuit and an output voltage 605 of the second charging circuit 323 can be changed at the same time by making equal the time 502 at which the first switching element 304 is switched and the time 602 at which the second switching element 324 is switched.

In addition, temporal compensation is realized by making the time constant 603, which is created in the second resistor 325 and the third fixed capacitor 328, equal to the time constant 403.

Moreover, by matching a capacitive value of the second fixed capacitor 319 with that of a parasitic capacitor 306 of the first fixed capacitor 305 using a trimming method or the like, a current transiently charged in the parasitic capacitor 306 is compensated by a current discharged from the second fixed capacitor 319.

Furthermore, voltage compensation is realized by causing the output voltage level 501 of the control voltage generating circuit 301 and the voltage level 601 divided by the second resistor 325 and the third resistor 327 to be equal to each other.

Thus, it is possible to stabilize an oscillation frequency of the crystal oscillator 317 within a short period of time by compensating the output voltage 504 of the control voltage generating circuit 301 with high precision.

As described above, the voltage-controlled crystal oscillator according to the present embodiment applies a control voltage through a low pass filter including a fixed capacitor and a resistor connected to a switch which is turned on at the start of operation for shorting both ends of the resistor. In the voltage-controlled crystal oscillator, a fixed capacitor synchronized with the switch is connected to the fixed capacitor of the low pass filter, and the connected fixed capacitor is charged to correct a transient characteristic of a control voltage at the time of supply of power. With this configuration, it is possible to suppress fluctuation of the control voltage. As a result, it is possible to stabilize an oscillation frequency within a short period of time.

The invention is advantageous in that a stabilized oscillation frequency can be obtained, while realizing a low noise performance in the same manner as in the known circuit. In addition, the invention is useful for a voltage-controlled crystal oscillator having a low pass filter for eliminating noises, for example.

Although the invention has been illustrated and described for the particular preferred embodiments, it is apparent to a person skilled in the art that various changes and modifications can be made on the basis of the teachings of the invention. It is apparent that such changes and modifications are within the spirit, scope, and intention of the invention as defined by the appended claims.

The present application is based on Japan Patent Application No. 2006-172374 filed on Jun. 22, 2006, the contents of which are incorporated herein for reference.

What is claimed is:

1. A voltage-controlled crystal oscillator having a voltage-variable capacitive element and a crystal vibrator connected to the voltage-variable capacitive element, comprising:
a control voltage generating circuit;
a first charging circuit which charges an output-side capacitive component;
a low pass filter having a first resistor and a first fixed capacitor;
a timer circuit which outputs a control signal;
a first switching element which is turned on in response to the control signal from the timer circuit so as to make both ends of the first resistor open-circuited;
a second charging circuit to which a signal synchronized with the control signal is input; and
a second fixed capacitor to which an output terminal of the second charging circuit is connected, and which connects a connection point between the first resistor and the first fixed capacitor,
wherein the low pass filter is arranged between the voltage-variable capacitive element and a connection point of the control voltage generating circuit and the first charging circuit.

2. The voltage-controlled crystal oscillator according to claim 1, wherein the second charging circuit includes:
a constant current source;
a second switching element to which the signal synchronized with the control signal from the timer circuit is input, and which is connected in series with the constant current source; and
a voltage restricting element which is connected in parallel with the second switching element,
wherein a connection point of the constant current source and the second switching element is connected to the second fixed capacitor.

3. The voltage-controlled crystal oscillator according to claim 1, wherein the second charging circuit includes:
a third switching element to which a signal synchronized with the control signal from the timer circuit is input, and which restricts supply of power;
a second resistor which is connected in series with the third switching element;
a third fixed capacitor which is connected in series with the second resistor; and
a voltage restricting element which is connected in parallel with the third fixed capacitor,
wherein a connection point of the second resistor and the third fixed capacitor is connected to the second fixed capacitor.

4. The voltage-controlled crystal oscillator according to claim 1, wherein the second charging circuit includes:
a third switching element to which the signal synchronized with the control signal from the timer circuit is input, and which restricts supply of power;
a second resistor which is connected in series with the third switching element;
a third resistor which is connected in series with the second resistor; and
a fourth fixed capacitor connected in parallel with the third resistor,
wherein a connection point of the second resistor and the third resistor is connected to the second fixed capacitor.
